(19) United States
(12) Patent Application Publication
(10) Pub. No.: US 2024/0413285 A1
(43) Pub. Date: Dec. 12, 2024

(54) DISPLAY DEVICE

(71) Applicant: AUO Corporation, Hsin-Chu (TW)

(72) Inventors: Wen-Ching SUNG, Hsin-Chu (TW); Kuo-Yu Huang, Hsin-Chu (TW)

(21) Appl. No.: 18/396,766

(22) Filed: Dec. 27, 2023

(30) Foreign Application Priority Data
Jun. 6, 2023 (TW) 112121077

(51) Int. Cl. H01L 33/62; H01L 25/075; H01L 25/16

(52) U.S. Cl. CPC H01L 33/62; H01L 25/0753; H01L 25/167

(57) ABSTRACT

A display device includes a substrate, a transistor, a first conductive feature, a conductive pad and a light-emitting device. The substrate has a first area. The transistor is located in the first area. The first conductive feature is located over the transistor and electrically connects a source/drain of the transistor. The first conductive feature includes a first protective layer and a first conductive layer. The first protective layer has a first thickness and at least includes titanium. The first conductive layer is located above the first protective layer, has a second thickness and includes aluminum. The second thickness is greater than the first thickness. The conductive pad is located on the first conductive feature and electrically connects the first conductive feature. The conductive pad at least includes nickel and gold. The light-emitting device is located on the conductive pad and electrically connects the conductive pad.

### RELATED APPLICATIONS

This application claims priority to Taiwan Application Serial Number 112121077, filed, Jun. 6, 2023, which is herein incorporated by reference.

### BACKGROUND

### Field of Invention

The present disclosure relates to a display device.

### Description of Related Art

Semiconductor components realize the electrical connection of different component areas through conductive features, in which the conductive features formed through stacking multiple material layers have a more outstanding conducting effect. Since, however, such conductive features includes different material layers, when manufacturing such conductive features, it's harder to precisely control the thickness and thus affects the performance of the semiconductor component.

Therefore, how to propose a display device that can solve the problem mentioned above is a problem that the industry urgently desire to invest R&D resource to solve.

### SUMMARY

In view of this, one aspect of the present disclosure provides a display device that can effectively solve the question mention above.

According to one embodiment of the present disclosure, a display device includes a substrate, a transistor, a first conductive feature, a conductive pad and a light-emitting device. The substrate has a first area. The transistor is located in the first area. The first conductive feature is located over the transistor and electrically connects a source/drain of the transistor. The first conductive feature includes a first protective layer and a first conductive layer. The first protective layer has a first thickness and at least includes titanium. The first conductive layer is located above the first protective layer, has a second thickness and at least includes aluminum. The second thickness is greater than the first thickness. The conductive pad is located on the first conductive feature and electrically connects the first conductive feature. The conductive pad at least includes nickel and gold. The light-emitting device is located on the conductive pad and electrically connects the conductive pad.

In some embodiments of the present disclosure, the display device further includes a conductive line. The conductive line is located in a second area of the substrate and electrically connects the first conductive feature. The conductive line includes a conductive line protective layer, a conductive line conducting layer and a cover layer. The conductive line protective layer has the first thickness. The conductive line conducting layer is located on the conductive line protective layer and has the second thickness. The cover layer conformally covers the conductive line protective layer and the conductive line conducting layer.

In some embodiments of the present disclosure, the cover layer includes a first cover layer and a second cover layer. The first cover layer conformally covers the conductive line protective layer and the conductive line conducting layer and has a third thickness. The second cover layer conformally covers the first cover layer and has a fourth thickness. The fourth thickness is greater than the third thickness.

In some embodiments of the present disclosure, the cover layer and the conductive line protective layer include a same material.

In some embodiments of the present disclosure, the display device further includes a first dielectric layer. The first dielectric layer is located on the substrate and has a first opening exposing a top surface of the first conductive feature. The first dielectric layer electrically isolates the light-emitting device and the first conductive feature. The conductive pad fills the first opening. A top surface of the conductive pad is higher than a top surface of the first dielectric layer.

In some embodiments of the present disclosure, the display device further includes a second dielectric layer and a second conductive feature. The second dielectric layer is located between the first dielectric layer and the transistor. The second conductive feature is located over the transistor and covered by the second dielectric layer. The second conductive feature electrically connects the first conductive feature and the transistor. The second dielectric layer has a second opening in the first area exposing a top surface of the second conductive feature. The first protective layer conformally covers the top surface of the second conductive feature and a plurality of sidewalls of the second opening. The first conductive layer fills the second opening.

In some embodiments of the present disclosure, the second conductive feature further includes a second protective layer and a second conductive layer. The second protective layer has the first thickness. The second conductive layer is located on the second protective layer and has the second thickness. The first protective layer of the first conductive feature directly contacts the second conductive layer of the second conductive feature.

In some embodiments of the present disclosure, the display device further includes a third conductive feature. The third conductive feature is located in a third area of the substrate. The third conductive feature includes a third protective layer, a third conductive layer and a cover layer. The third protective layer has the first thickness. The third conductive layer is located on the third protective layer and has the second thickness. The cover layer conformally covers the third protective layer and the third conductive layer.

In some embodiments of the present disclosure, the cover layer includes a first cover layer and a second cover layer. The first cover layer conformally covers the third protective layer and the third conducting layer and has a third thickness. The second cover layer conformally covers the first cover layer and has a fourth thickness. The fourth thickness is greater than the third thickness.

In some embodiments of the present disclosure, a top surface of the conductive pad is higher than a top surface of the third conductive feature.

Another aspect of the present disclosure provides a display device.

According to one embodiment of the present disclosure, a display device includes a display device includes a substrate, a transistor, a first conductive feature, a first dielectric layer and a conductive pad. The substrate has a first area. The transistor is located in the first area. The first conductive feature is located over the transistor and electrically connects a source/drain of the transistor. The first conductive feature includes a first protective layer and a first conductive layer. The first protective layer has a first thickness and at least includes titanium. The first conductive layer is located above the first protective layer, has a second thickness and at least includes aluminum. The second thickness is greater than the first thickness. The first dielectric layer is located on the substrate and has a first opening exposing a top surface of the first conductive feature. The conductive pad is located on the first conductive feature and electrically connects the first conductive feature. The conductive pad at least includes nickel and gold.

In some embodiments of the present disclosure, the display device further includes a conductive line. The conductive line is located in a second area of the substrate and electrically connects the first conductive feature. The conductive line includes a conductive line protective layer, a conductive line conducting layer and a cover layer. The conductive line protective layer has the first thickness. The conductive line conducting layer is located on the conductive line protective layer and has the second thickness. The cover layer conformally covers the conductive line protective layer and the conductive line conducting layer.

In some embodiments of the present disclosure, the cover layer includes a first cover layer and a second cover layer. The first cover layer conformally covers the conductive line protective layer and the conductive line conducting layer and has a third thickness. The second cover layer conformally covers the first cover layer and has a fourth thickness. The fourth thickness is greater than the third thickness.

In some embodiments of the present disclosure, the cover layer and the conductive line protective layer include a same material.

In some embodiments of the present disclosure, the display device further includes a second dielectric layer and a second conductive feature. The second dielectric layer is located between the first dielectric layer and the transistor. The second conductive feature is located over the transistor and covered by the second dielectric layer. The second conductive feature electrically connects the first conductive feature and the transistor. The second dielectric layer has a second opening in the first area exposing a top surface of the second conductive feature. The first protective layer conformally covers the top surface of the second conductive feature and a plurality of sidewalls of the second opening. The first conductive layer fills the second opening.

In the aforementioned embodiments of the present disclosure, in the display device of some embodiments of the present disclosure, since the display device has conductive feature with Al/Ti or Al/Mo structure, the etching uniformity of the conductive feature can be ensured to more precisely control the thickness of the first conductive feature and to simultaneously improve the process stability. On the other hand, conductive feature with Al/Ti or Al/Mo structure can also provide better electrical transmission efficiency. On the other hand, the conductive line of the display device is consist of protective layer, conductive layer and cover layer, which can further improve the electrical transmission efficiency. Furthermore, the height of the conductive pad is taller than the first dielectric layer and the third conductive feature, which can avoid other unexpected electrical connection when the light-emitting device electrically connects the conductive pad.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a display device according to some embodiment of the present disclosure.

FIG. 2 is a local enlarged top view of the display device based on frame A of FIG. 1.

FIG. 3A is a cross-sectional side view of the display device based on the hatching line A-A′ of FIG. 2.

FIG. 3B is a cross-sectional side view of the display device based on the hatching line B-B′ of FIG. 2.

FIG. 3C is a cross-sectional side view of the display device based on the hatching line C-C′ of FIG. 2.

FIG. 3D is a local enlarged cross-sectional side view of the display device based on frame A′ of FIG. 3C.

FIG. 4A is a local enlarged cross-sectional side view of the conductive line of the display device according to some embodiments of the present disclosure.

FIG. 4B is a local enlarged cross-sectional side view of the conductive line of the display device according to other embodiments of the present disclosure.

FIG. 5 is a schematic view of the display device according to other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “about”, “about”, “approximately” or “substantially” generally means within 20 percent, or within 10 percent, or within 20 percent of a given value or range of 5. Numerical quantities given herein are approximations, indicating that the use of terms such as “about,” “approximately,” “approximately,” or “substantially” can be inferred when not explicitly stated.

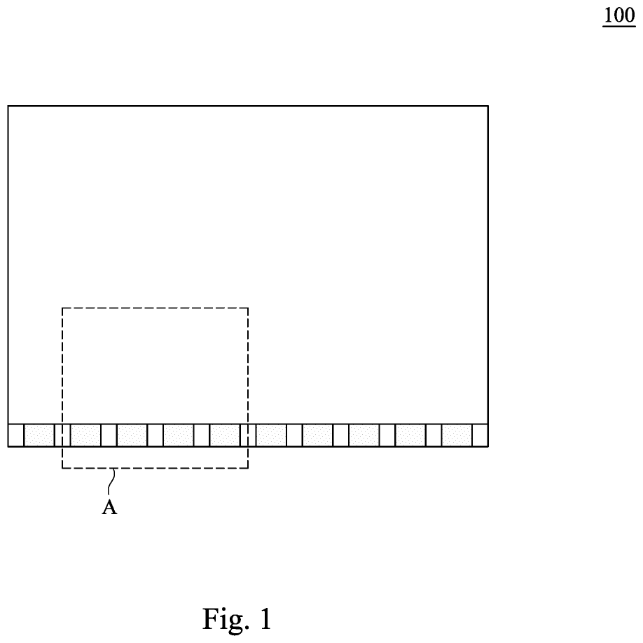

Please refer to FIG. 1, FIG. 1 is a schematic view of a display device 100 according to some embodiment of the present disclosure. Some of the embodiments of the present disclosure provide a display device 100. In some embodiments, the display device 100 is a non-spliced display panel.

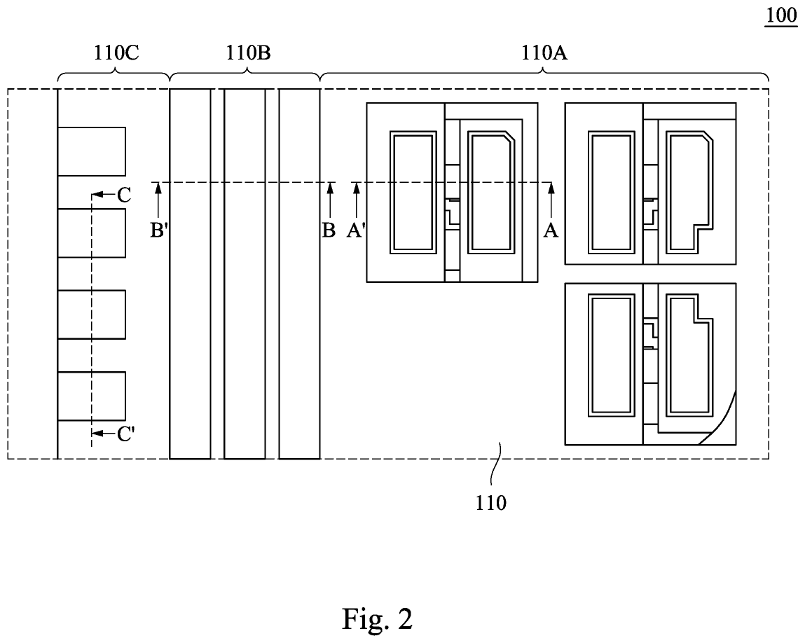

Please refer to FIG. 2, FIG. 2 is a local enlarged top view of the display device 100 based on frame A of FIG. 1. The display device 100 includes a substrate 110. The substrate 110 has a first area 110A, a second area 110B and a third area 110C. In some embodiments, the first area 110A includes a pixel area, the second area 110B includes a trace area, the third area 110C includes a package area, such as a chip on film area. In come embodiments, the substrate is translucent.

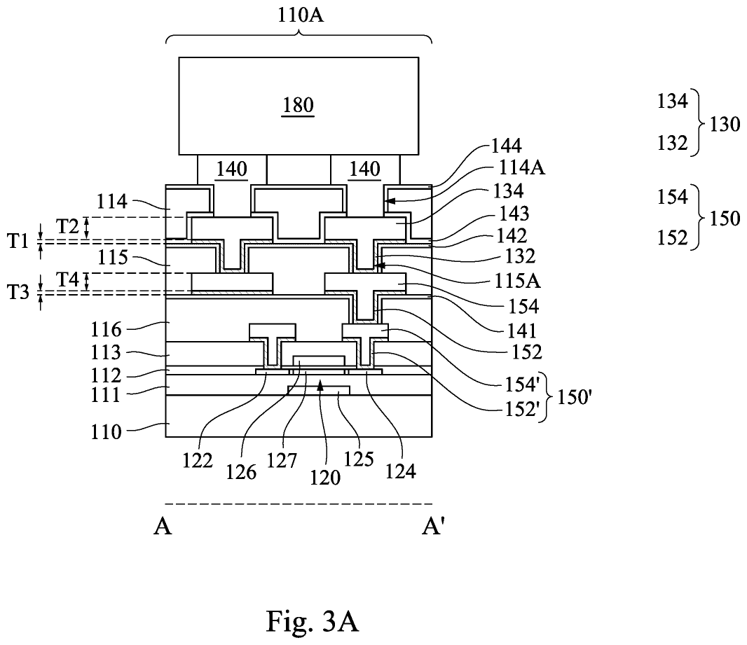

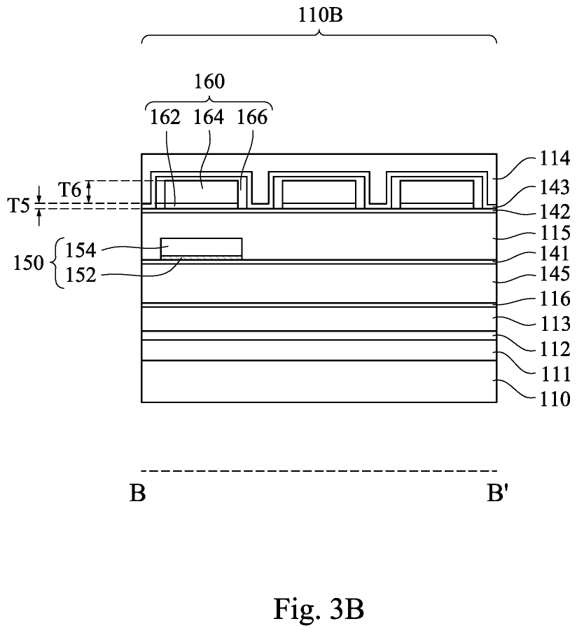

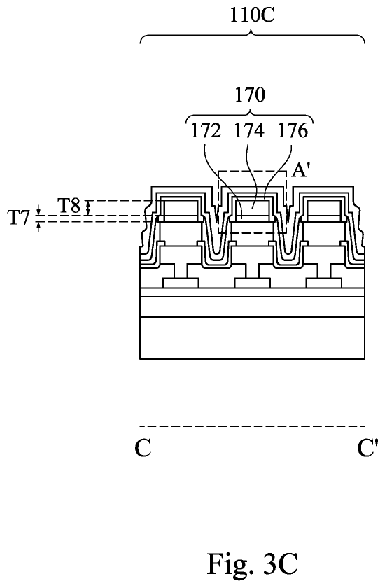

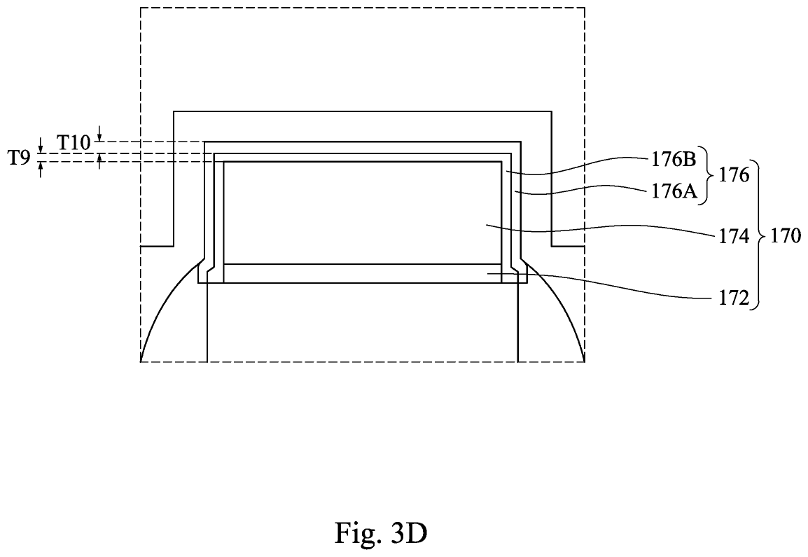

Please refer to FIG. 3A, FIG. 3A is a cross-sectional side view of the display device 100 based on the hatching line A-A′ of FIG. 2. The display device 100 further includes a transistor 120, a first conductive feature 130, a conductive pad 140 and a light-emitting device 180. The transistor 120 is located in the first area 110A of the substrate 110. The first conductive feature 130 is located over the transistor 120 and electrically connects a source/drain 124 of the transistor 120. In some embodiments, the transistor 120 is disposed on the buffer layer 111 located on the substrate 110 and has a gate insulating layer 112 covering the semiconductor active area 127. The material of the semiconductor active area 127 can include poly silicon. The gate electrode 126 is located on the semiconductor active area 127 and the gate insulating layer 112. The material of the gate electrode 126 can include molybdenum. In some embodiments, the gate electrode 126 can electrically connects the conductive layer 125 through a gate insulating via. The conductive layer 125 can include molybdenum. The first conductive feature 130 includes a first protective layer 132 and a first conductive layer 134. The first protective layer 132 has a first thickness T1 and at least includes titanium, molybdenum or a combination thereof. In some embodiments, the first protective layer 132 includes molybdenum oxide, molybdenum tantalite, titanium nitride, titanium alloy, molybdenum alloy, minor doping material includes titanium or molybdenum, minor doping material includes the combination thereof, of a combination thereof. The first conductive layer 134 is located above the first protective layer 132, has a second thickness T2 and at least includes aluminum. The second thickness T2 is greater than the first thickness T1. The first conductive layer 134 includes aluminum alloy, minor aluminum nitride doping or other minor doping materials.

Following the above paragraph, compare to the conductive feature formed by Ti/Al/Ti stack, the first conductive feature 130 formed by the first protective layer 132 and the first conductive layer 134 can avoid the formation of residue after the etching process, and can precisely control the thickness of the first conductive feature 130. Aluminum has a greater etching rate than titanium (or molybdenum), such that an under-etched titanium tends to form in a Ti/Al/Ti structure and blocks the etching of aluminum, which cause the under-etching of the conductive feature and the increase of the thickness of the conductive feature. Compare to the Ti/Al/Ti structure, the Al/Ti structure or Al/Mo structure of the first conductive feature 130 can be uniformly etched since there is no titanium covers the top of the structure without under-etching the aluminum under titanium caused by the slower etching rate of titanium, and thus the thickness of the first conductive feature 130 can be precisely controlled and the process stability can be improved. In some embodiments, the thickness of the first conductive feature 130 is in a range of about 1000 Å to 10000 Å. In some embodiments, the thickness of the first protective layer 132 is about 500 Å, and the thickness of the first conductive layer 134 is about 6000 Å. In some embodiments, the first conductive feature 130 will be partially cover by an isolation layer 143. The material of the isolation layer 143 can includes silicon nitride. In some embodiments, the isolation layer 143 has a thickness of about 2000 Å.

Please continue to refer to FIG. 3A, the conductive pad 140 is located on the first conductive feature 130 and electrically connects the first conductive feature 130. The conductive pad at least includes nickel-gold (NiAu). In some embodiments, the thickness of the conductive pad 140 is in a range of about 5 μm to 100 μm. The light-emitting device 180 is located on the conductive pad 140 and electrically connects the conductive pad 140. In some embodiments, the display device 100 further includes a first dielectric layer 114. The first dielectric layer 114 is located on the substrate 110 and has a first opening 114A exposing a top surface of the first conductive feature 130. In some embodiments, an isolation layer 144 will fill in the first opening 114A. The isolation layer 144 can includes dielectric materials, such as silicon nitride. In some embodiments, the isolation layer 144 has a thickness of about 2000 Å. The first dielectric layer 114 is located between the light-emitting device 180 and the first conductive feature 130. In some embodiments, the first dielectric layer 114 includes organic dielectric layer. In some embodiments, the first dielectric layer 114 includes multiple layers. These layers can be formed using various deposition processes based on the need, such as physical vapor deposition (PVD) process, atomic layer deposition (ALD) process, molecular beam epitaxy (MBE) process, other similar process of the combination thereof.

Following the above paragraph, the conductive pad 140 fills the first opening 114A and a top surface of the conductive pad 140 is higher than a top surface of the first dielectric layer 114. The height difference between the conductive pad 140 and the first dielectric layer 114 can avoid the contact between the light-emitting device 180 and other structure in the first area 110A and causes short. In some embodiments, the cross-sectional shape of the conductive pad 140 along the hatching line A-A′ is T-shaped to provide a better conducting effect, and the top surface of the conductive pad 140 has a larger area to stably connects the light-emitting device 180.

Please continue to refer to FIG. 3A, In some embodiments, the display device 100 further includes a second dielectric layer 115 and a second conductive feature 150. The second dielectric layer 115 is located between the first dielectric layer 114 and the transistor 120. In some embodiments, an isolation layer 142 will covers the second dielectric layer 115 and extends to the sidewall of the first conductive feature 130. The material of the isolation layer 142 can includes silicon nitride. In some embodiments, the isolation layer 142 has a thickness of about 2000 Å. The second conductive feature 150 is located over the transistor 120 and covered by the second dielectric layer 115. In some embodiments, the second conductive feature 150 is partially embedded in a third dielectric layer 116 located between the second dielectric layer 115 and the substrate 110. In some embodiments, an isolation layer 141 is included between the second dielectric layer 115 and the third dielectric layer 116. The material of the isolation layer 141 can includes silicon nitride. In some embodiments, the isolation layer 141 has a thickness of about 2000 Å. The second conductive feature 150 electrically connects the first conductive feature 130 and the transistor 120. The second dielectric layer 115 has a second opening 115A in the first area 110A exposing a top surface of the second conductive feature 150. The first protective layer 132 is located on the top surface of the second conductive feature 150 and a plurality of sidewalls 180a of the second opening 115A, and the first conductive layer 134 fills the second opening 115A. The first protective layer 132 located on the top surface of the second conductive feature 150 and a plurality of sidewalls 180a of the second opening 115A can prevent the sidewalls 180a of the second opening 115A from direct contact with the first conductive layer 134 to maintain the conducting effect of the first conductive feature 130. In some embodiments, the second dielectric layer 115 includes organic dielectric layer. In some embodiments, the second dielectric layer 115 includes multiple layers. These layers can be formed using various deposition processes based on the need, such as physical vapor deposition (PVD) process, atomic layer deposition (ALD) process, molecular beam epitaxy (MBE) process, other similar process of the combination thereof.

Please continue to refer to FIG. 3A, in some embodiments, the second conductive feature 150 further includes a second protective layer 152 and a second conductive layer 154. The second protective layer 152 has a third thickness T3. The second conductive layer 154 is located on the second protective layer 152 and has a fourth thickness T4 greater than the third thickness T3. In some embodiments, the thickness of the second protective layer 152 is about 500 Å, and the thickness of the second conductive layer 154 is about 6000 Å. In some embodiments, the first protective layer 132 of the first conductive feature 130 directly contact the second conductive layer 154 of the second conductive feature 150. The first conductive feature 130 and the second conductive feature 150 collectively form alternating titanium (or molybdenum) material layer (such as the first protective layer 132, the second protective layer 152) and aluminum material layer (such as the first conductive layer 134, the second conductive layer 154), which can provides a greater electrical transmission efficiency. The reason is that when the titanium (or molybdenum) material layer contacts the aluminum material layer, the material impedance of the aluminum material layer can be reduced, and thus improves the electrical transmission efficiency of the aluminum material layer. Furthermore, the process steps of forming the first conductive feature 130 and the second conductive feature 150 is simpler than the process steps of forming the Ti/Al/Ti conductive feature, which can reduce the manufacturing cost and improve the process yield. In some embodiments, the thickness of the second conductive feature 150 is in a range of about 1000 Å to 10000 Å.

Please continue to refer to FIG. 3A, in some embodiments, the amount of the second conductive feature 150 can be increase or decrease based ion electrical needs to electrically connect various layers of the display device 100. As an example, two second conductive features 150, 150′ is shown in FIG. 3A and is stacked perpendicular to the substrate 110. Similar to the second conductive feature 150 mentioned above, the second conductive feature 150′ includes a second protective layer 152′ and a second conductive layer 154′, and two second conductive features 150, 150′ forms alternately stacked titanium material layer and aluminum material layer. In some embodiments, the titanium material layer is replaced by molybdenum material layer such that the two second conductive features 150, 150′ forms alternately stacked molybdenum material layer and aluminum material layer. In some embodiments, the second conductive feature 150′ is covered by a third dielectric layer 116, and the second conductive feature 150′ penetrates the interlayer dielectric (ILD) layer 113 located between the third dielectric layer 116 and the substrate 110. Furthermore, in some embodiments, the second conductive features 150 is distributed in the first area 110A and the second area 110B (please refer to FIG. 3A and FIG. 3B) of the substrate 110. In some embodiments, the thickness of the second protective layer 152′ is about 500 Å, and the thickness of the second conductive layer 154′ is about 6000 Å. In some embodiments, the thickness of the second conductive feature 150′ is in a range of about 1000 Å to 10000 Å.

Please refer to FIG. 3B, FIG. 3B is a cross-sectional side view of the display device 100 based on the hatching line B-B′ of FIG. 2. In some embodiments, the display device 100 further includes a conductive line 160. The conductive line 160 is located in the second area 110B of the substrate 110 and electrically connects the first conductive feature 130. The conductive line 160 includes a conductive line protective layer 162, a conductive line conducting layer 164 and a conductive line cover layer 166. The conductive line protective layer 162 has a fifth thickness. The conductive line conducting layer 164 is located on the conductive line protective layer 162 and has a sixth thickness T6 greater than the fifth thickness T5. In some embodiments, the thickness of the conductive line protective layer 162 is about 500 Å, and the thickness of the conductive line conducting layer 164 is about 1000 Å. The conductive line cover layer 166 conformally covers the conductive line protective layer 162 and the conductive line conducting layer 164 to improve the electrical transmission efficiency of the conductive line 160 and to simultaneously improve the process yield of the conductive line 160. In some embodiments, the conductive line protective layer 162 includes similar or the same material as the first protective layer 132, such as molybdenum oxide, molybdenum tantalite, titanium nitride, titanium alloy, molybdenum alloy, minor doping material includes titanium or molybdenum, minor doping material includes the combination thereof, of a combination thereof. In some embodiments, the conductive line conducting layer 164 includes similar or the same material as the first conductive layer 134, such as aluminum. In some embodiments, the conductive line cover layer 166 and the conductive line protective layer 162 includes the same material. In some embodiments, the thickness of the conductive line protective layer 162 and the conductive line conducting layer 164 is in a range of about 1000 Å to 10000 Å. In some embodiments, the display device 100 further includes a fourth dielectric layer 145, and the material of the fourth dielectric layer 145 includes organic dielectric layer.

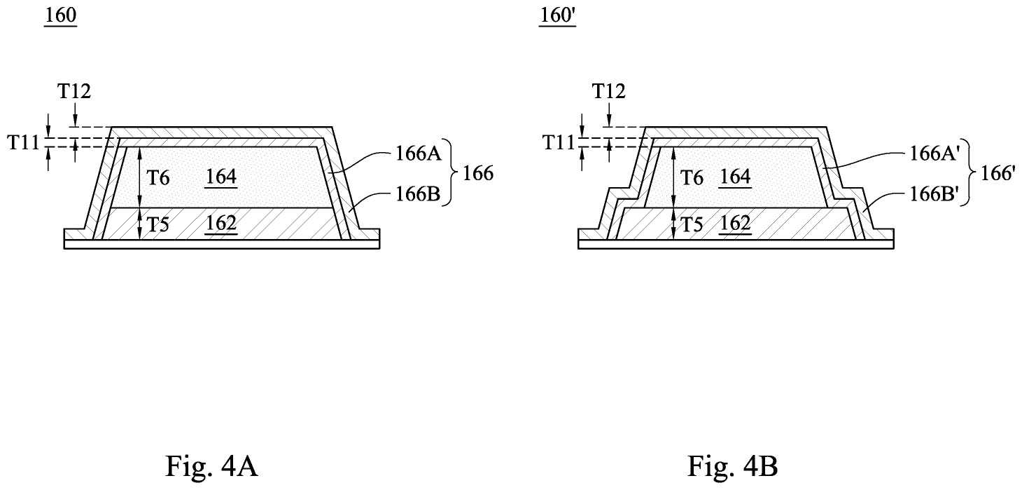

Please refer to FIG. 4A, FIG. 4A is a local enlarged cross-sectional side view of the conductive line 160 of the display device 100 according to some embodiments of the present disclosure. In some embodiments, the conductive line cover layer 166 includes a first conductive line cover layer 166A and a second conductive line cover layer 166B. The first conductive line cover layer 166A conformally covers the conductive line protective layer 162 and the conductive line conducting layer 164 and has a eleventh thickness T11. The second conductive line cover layer 166B conformally covers the first conductive line cover layer 166A and has a twelfth thickness T12 greater than the eleventh thickness T11. In some embodiments, the first conductive line cover layer 166A includes aluminum, and the second conductive line cover layer 166B includes titanium, which helps the conductive line cover layer 166 to conformally formed on the conductive line protective layer 162 and the conductive line conducting layer 164. The conductive line protective layer 162, the conductive line conducting layer 164 and the conductive line cover layer 166 collectively form alternating titanium material layer (such as the conductive line protective layer 162, the conductive line cover layer 166) and aluminum material layer (such as the conductive line conducting layer 164), which enables the greater electrical transmission efficiency of the conductive line 160. In some embodiments, the cross-sectional contour of the conductive line 160 is substantially a trapezoid. In some embodiments, the thickness of the conductive line cover layer 166 is in a range of about 150 Å to 3000 Å. In other embodiments, the conductive line cover layer 166 has only the second conductive line cover layer 166B.

Please refer to FIG. 4B, FIG. 4B is a local enlarged cross-sectional side view of the conductive line 160′ of the display device 100 according to other embodiments of the present disclosure. The cross-sectional contour of the conductive line 160′ is formed by a stack of two trapezoids. In some embodiments, the cross-sectional contour of the conductive line 160′ is a trapezoid with a narrower topline and a wider baseline (i.e. the side that is away from the substrate 110 is narrower; the side that is adjacent to the substrate is wider). The difference of the cross-sectional contour of the conductive line 160′ comes from error caused by the process. In some embodiments, the cross-sectional width of the conductive line protective layer 162′ is greater than the width of the conductive line conducting layer 164′, and part of the top surface of the conductive line protective layer 162′ is not covered by the conductive line conducting layer 164′. In some embodiments, the conductive line cover layer 166′ is formed conformally along multiple sidewalls and the top surface of the conductive line protective layer 162′ and multiple sidewalls and the top surface of the conductive line conducting layer 164′. In some embodiments, an indium tin oxide (ITO) layer can be optionally formed on the conductive line 160 of FIG. 4A or the conductive line 160′ of FIG. 4B. In some embodiments, the thickness of the ITO layer is in a range of about 150 Å to 2000 Å.

Please refer to FIG. 3C, FIG. 3C is a cross-sectional side view of the display device 100 based on the hatching line C-C′ of FIG. 2. In some embodiments, the display device 100 further includes a third conductive feature 170. The third conductive feature is located in the third area 110C of the substrate 110. The third conductive feature 170 includes a third protective layer 172, a third conductive layer 174 and a third cover layer 176. The third protective layer 172 has a seventh thickness T7. The third conductive layer 174 is located on the third protective layer 172 and has an eighth thickness greater T8 than the seventh thickness T7. The third cover layer 176 conformally covers the third protective layer 172 and the third conductive layer 174 to improve the electrical transmission efficiency of the third conductive layer 174. In some embodiments, the cross-sectional contour of the third conductive feature 170 that has the third cover layer 176 can be similar to the conductive line 160 of FIG. 4A or the conductive line 160′ of FIG. 4B. In some embodiments, the third conductive feature 170 is the conductive pad of chip on film that is used to electrically connect other components. In some embodiments, the material of the third protective layer 172 and the third conductive layer 174 is similar to the first protective layer 132 and the first conductive layer 134. In some embodiments, a top surface of the conductive pad 140 is higher than a top surface of the third conductive feature 170 to further prevent the light-emitting device 180 from unexpected electrical connection with the third conductive feature 170.

Following the above paragraph, in some embodiments, please refer to FIG. 3D, FIG. 3D is a local enlarged cross-sectional side view of the display device 100 based on frame A′ of FIG. 3C. The third cover layer 176 includes a first sub-cover layer 176A and a second sub-cover layer 176B. The first sub-cover layer 176A conformally covers the third protective layer 172 and the third conductive layer 174 and has a ninth thickness T9. The second sub-cover layer 176B conformally covers the first sub-cover layer 176A and has a tenth thickness T10, and the tenth thickness T10 is greater than the ninth thickness T9 to let the third conductive feature 170 has a better process yield. In some embodiments, the first sub-cover layer 176A and the second sub-cover layer 176B can cover the third protective layer 172 and the third conductive layer 174 similar or the same as the first conductive line cover layer 166A, 166A′ and the second conductive line cover layer 166B, 166B′. In some embodiments, the thickness of the third protective layer 172 and the third conductive layer 174 is in a range of about 1000 Å to 10000 Å. In some embodiments, the thickness of the third protective layer 172 is about 500 Å, and the thickness of the third conductive layer 174 is about 6000 Å. In some embodiments, the thickness of the third cover layer cover is in a range of about 150 Å to 3000 Å.

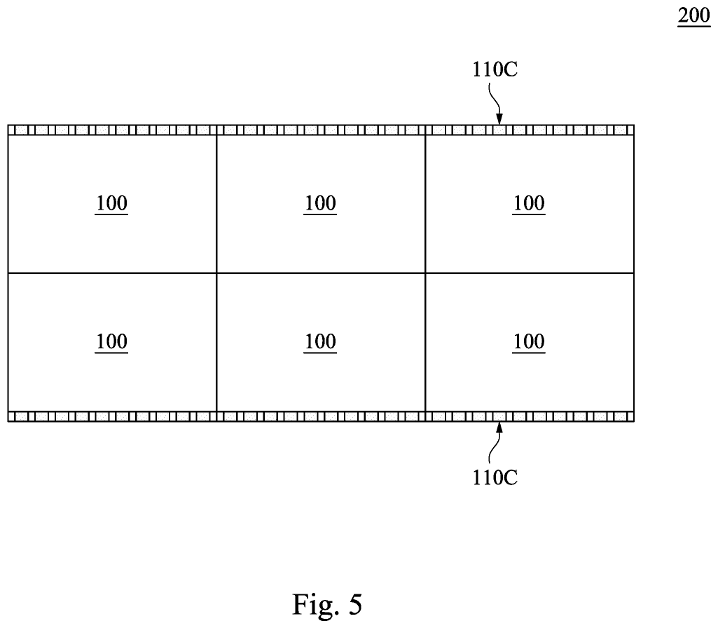

Please refer to FIG. 5, FIG. 5 is a schematic view of the display device 200 according to other embodiments of the present disclosure. In some embodiments, the display device 200 is a spliced display panel that consists of a plurality of the display device 100 of FIG. 1. In some embodiments, the third area 110C of the substrate 110 of the display device 100 is disposed adjacent to the two opposite sides of the display device 200.

According to the foregoing recitations of the embodiments of the disclosure, it can be seen that in the display device of some embodiments of the present disclosure, since the display device has conductive feature with Al/Ti or Al/Mo structure, the etching uniformity of the conductive feature can be ensured to more precisely control the thickness of the first conductive feature and to simultaneously improve the process stability. On the other hand, conductive feature with Al/Ti or Al/Mo structure can also provide better electrical transmission efficiency. On the other hand, the conductive line of the display device is consist of protective layer, conductive layer and cover layer, which can further improve the electrical transmission efficiency. Furthermore, the height of the conductive pad is taller than the first dielectric layer and the third conductive feature, which can avoid other unexpected electrical connection when the light-emitting device electrically connects the conductive pad.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A display device, comprising:
a substrate having a first area;
a transistor located in the first area;
a first conductive feature located over the transistor and electrically connected to a source/drain of the transistor, wherein the first conductive feature comprises:
a first protective layer having a first thickness and at least comprising titanium;
a first conductive layer located above the first protective layer, having a second thickness and at least comprising aluminum, wherein the second thickness is greater than the first thickness;
a conductive pad located on the first conductive feature, electrically connected to the first conductive feature and at least comprising nickel and gold; and
a light-emitting device located on the conductive pad and electrically connected to the conductive pad.

2. The display device of claim 1, further comprising:
a conductive line located in a second area of the substrate and electrically connected the first conductive feature, wherein the conductive line comprises:
a conductive line protective layer having the first thickness;
a conductive line conducting layer located on the conductive line protective layer and having the second thickness; and
a cover layer conformally covering the conductive line protective layer and the conductive line conducting layer.

3. The display device of claim 2, wherein the cover layer comprises:
a first cover layer conformally covering the conductive line protective layer and the conductive line conducting layer and having a third thickness; and
a second cover layer conformally covering the first cover layer and having a fourth thickness, wherein the fourth thickness is greater than the third thickness.

4. The display device of claim 2, wherein the cover layer and the conductive line protective layer comprises a same material.

5. The display device of claim 1, further comprising:
a first dielectric layer located on the substrate and having a first opening exposing a top surface of the first conductive feature, wherein the first dielectric layer electrically isolates the light-emitting device and the first conductive feature, the conductive pad fills the first opening and a top surface of the conductive pad is higher than a top surface of the first dielectric layer.

6. The display device of claim 5, further comprising:
a second dielectric layer located between the first dielectric layer and the transistor; and
a second conductive feature located over the transistor and covered by the second dielectric layer, wherein the second conductive feature electrically connects the first conductive feature and the transistor,
wherein the second dielectric layer has a second opening in the first area exposing a top surface of the second conductive feature, the first protective layer conformally covers the top surface of the second conductive feature and a plurality of sidewalls of the second opening, and the first conductive layer fills the second opening.

7. The display device of claim 6, wherein the second conductive feature further comprises:
a second protective layer having the first thickness; and
a second conductive layer located on the second protective layer and having the second thickness, wherein the first protective layer of the first conductive feature directly contacts the second conductive layer of the second conductive feature.

8. The display device of claim 1, further comprising:
a third conductive feature located in a third area of the substrate, wherein the third conductive feature comprises:
a third protective layer having the first thickness;
a third conductive layer located on the third protective layer and having the second thickness; and
a cover layer conformally covering the third protective layer and the third conductive layer.

9. The display device of claim 8, wherein the cover layer comprises:
a first cover layer conformally covering the third protective layer and the third conducting layer and having a third thickness; and
a second cover layer conformally covering the first cover layer and having a fourth thickness, wherein the fourth thickness is greater than the third thickness.

10. The display device of claim 9, wherein a top surface of the conductive pad is higher than a top surface of the third conductive feature.

11. A display device, comprising:
a substrate having a first area;
a transistor located in the first area;
a first conductive feature located over the transistor and electrically connected to a source/drain of the transistor, wherein the first conductive feature comprises:
a first protective layer having a first thickness and at least comprising titanium;
a first conductive layer located above the first protective layer, having a second thickness and at least comprising aluminum, wherein the second thickness is greater than the first thickness;
a first dielectric layer located on the substrate and having a first opening exposing a top surface of the first conductive feature; and
a conductive pad located on the first conductive feature, electrically connected to the first conductive feature and at least comprising nickel and gold.

12. The display device of claim 11, further comprising:
a conductive line located in a second area of the substrate and electrically connected the first conductive feature, wherein the conductive line comprises:
a conductive line protective layer having the first thickness;
a conductive line conducting layer located on the conductive line protective layer and having the second thickness; and
a cover layer conformally covering the conductive line protective layer and the conductive line conducting layer.

13. The display device of claim 12, wherein the cover layer comprises:
a first cover layer conformally covering the conductive line protective layer and the conductive line conducting layer and having a third thickness; and
a second cover layer conformally covering the first cover layer and having a fourth thickness, wherein the fourth thickness is greater than the third thickness.

14. The display device of claim 12, wherein the cover layer and the conductive line protective layer comprises a same material.

15. The display device of claim 11, further comprising:
a second dielectric layer located between the first dielectric layer and the transistor; and
a second conductive feature located over the transistor and covered by the second dielectric layer, wherein the second conductive feature electrically connects the first conductive feature and the transistor,
wherein the second dielectric layer has a second opening in the first area exposing a top surface of the second conductive feature, the first protective layer conformally covers the top surface of the second conductive feature and a plurality of sidewalls of the second opening, and the first conductive layer fills the second opening.
